(19) United States
(12) Patent Application Publication
(10) Pub. No.: US 2014/0264655 A1
(43) Pub. Date: Sep. 18, 2014

(54) SURFACE ROUGHENING TO REDUCE ADHESION IN AN INTEGRATED MEMS DEVICE

(71) Applicant: InvenSense, Inc., San Jose, CA (US)

(72) Inventors: Kirt Reed WILLIAMS, Portola Valley, CA (US); Kegang HUANG, Fremont, CA (US); Wencheng XU, Sunnyvale, CA (US); Jongwoo SHIN, Pleasanton, CA (US); Martin LIM, San Mateo, CA (US)

(73) Assignee: InvenSense, Inc., San Jose, CA (US)

(21) Appl. No.: 14/061,152

(22) Filed: Oct. 23, 2013

Related U.S. Application Data
(60) Provisional application No. 61/780,776, filed on Mar. 13, 2013.

(51) Int. Cl. B81B 3/00; B81C 1/00

(52) U.S. Cl. CPC B81B 3/0021; B81C 1/00341
USPC 257/416; 257/415; 257/421; 438/50

(57) ABSTRACT

In an integrated MEMS device, moving silicon parts with smooth surfaces can stick together if they come into contact. By roughening at least one smooth surface, the effective area of contact, and therefore surface adhesion energy, is reduced and hence the sticking force is reduced. The roughening of a surface can be provided by etching the smooth surfaces in gas, plasma, or liquid with locally non-uniform etch rate. Various etch chemistries and conditions lead to various surface roughness.

### CROSS-REFERENCE TO RELATED APPLICATION

This application claims benefit under 35 USC 119(e) of U.S. Provisional Patent Application No. 61/780,776, filed on Mar. 13, 2013, entitled “SURFACE ROUGHENING TO PREVENT ADHESION IN MICRODEVICES,” which is incorporated herein by reference in its entirety.

### FIELD OF THE INVENTION

The present invention relates generally to integrated MEMS devices and more particularly to a system and method for reducing adhesion in such devices.

### BACKGROUND

Integrated MEMS devices (with dimensions from 0.01 to 1000 um) have moving MEMS parts with smooth surfaces. When the surfaces come into contact, they can adhere or stick together (often referred to as “stiction”). The adhesion force, which must be overcome in order to separate the parts from each other, originates from the surface adhesion energy that is proportional to the area of atomic contact. Accordingly what is needed is a system and method to reduce the adhesion force in such devices. The present invention addresses such a need.

### SUMMARY

Methods and systems for reducing adhesion in an integrated MEMS device are disclosed. In a first aspect, an integrated MEMS device comprises a MEMS substrate having a first contacting surface; a base substrate coupled to the MEMS substrate having a second contacting surface of the MEMS device. At least one of the first contacting surface and the second contacting surface is roughened in a predetermined manner.

In a second aspect, a method to reduce surface adhesion forces in an integrated MEMS device is disclosed. The integrated MEMS device including a MEMS substrate having a first contacting surface and a base substrate coupled to the MEMS substrate having a second contacting surface, the method comprises etching at least one of the first contacting surface and the second contacting surface to roughen at least one of the first contacting surface and the second contacting surface.

In a third aspect, a method to reduce surface adhesion forces in an integrated MEMS device is disclosed. The integrated MEMS device including a MEMS substrate having a first contacting surface and a base substrate coupled to the MEMS substrate having a second contacting surface. The method comprises depositing a rough film onto one of the first contacting surface and the second contacting surface; and plasma etching the rough film through and into the one of the first contacting surface and the second contacting surface. The roughness on the rough film will be transferred into the one of the first contacting surface and the second contacting surface.

### BRIEF DESCRIPTION OF THE DRAWINGS

FIG. 1A shows a cross section drawing of a bonded base substrate-MEMS device with moving MEMS silicon parts which can move and touch the bump stops on base substrate.

FIG. 1B shows a cross section drawing of a bonded base substrate-MEMS device with moving MEMS silicon parts which can move and touch the bump stops on the base substrate and at least one of the contacting surfaces are roughened.

FIGS. 2A-2E show a series of cross section drawings of base substrate processing steps to complete the base substrate with bump stops having a rough surface.

FIGS. 3A-3D show a series of cross section drawings of a first embodiment of MEMS substrate processing steps to complete a MEMS wafer with silicon structures having a rough surface.

FIGS. 4A-4D show a series of cross-section drawings of a second embodiment of a MEMS substrate processing steps to provide a rough surface on the MEMS substrate.

### DETAILED DESCRIPTION

The present invention relates generally to integrated MEMS devices and more particularly to a system and method for reducing adhesion in such devices.

The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

In the described embodiments Micro-Electro-Mechanical Systems (MEMS) refers to a class of structures or devices fabricated using semiconductor-like processes and exhibiting mechanical characteristics such as the ability to move or deform. MEMS often, but not always, interact with electrical signals. MEMS devices include but not limited to gyroscopes, accelerometers, magnetometers, microphones, and pressure sensors.

In the described embodiments, MEMS device may refer to a semiconductor device implemented as a micro-electro-mechanical system. MEMS structure may refer to any feature that may be part of a larger MEMS device. In the described embodiments, device layer may refer to the silicon substrate in which the MEMS structure is formed. An Engineered silicon-on-insulator (ESOI) wafer may refer to a SOI wafer with cavities underneath the device wafer. Base substrate may include CMOS substrate or any other semiconductor substrate. In certain embodiments, base substrate may include electrical circuits. Handle wafer typically refers to a thicker semiconductor substrate used as a carrier for the MEMS substrate. In certain embodiments, the handle wafer is the base of a silicon-on-insulator wafer. Handle substrate, handle layer, and handle wafer can be interchanged. The MEMS substrate includes the device layer and the handle layer.

In the described embodiments, a cavity may refer to an opening in a substrate wafer and enclosure may refer to a fully enclosed space. Standoff may be a vertical structure providing electrical contact.

A MEMS device with one or both contacting surfaces being roughened, and fabrication methods to achieve rough surfaces for one or both surfaces of the two contacting parts are disclosed. The roughness of the contacting surfaces reduces the surface adhesion energy, therefore the sticking force, preventing the contacting surfaces stick to each other.

FIG. 1A shows a cross section drawing of a bonded base substrate-MEMS device 100 with movable structure 106a which can come in contact with the bump stop 110a on base substrate 107. The MEMS substrate 111 includes a handle substrate 101 with cavities etched into it and a device layer 103, bonded together with a thin dielectric film 102 (such as silicon oxide) in between. In some embodiments, the device layer 103 is made of single crystal silicon. Standoff 104 is formed with a germanium (Ge) film 105 on top of the standoff 104. The MEMS substrate 111 is completed after the device layer 103 is patterned and etched to form movable structure 106a.

The MEMS device 100 includes a base substrate 107. A layer of conductive material 108 is deposited on the base substrate to provide electrical connection from the device layer 103 to the base substrate 107. In an embodiment, the base substrate-MEMS integration is achieved by eutectic bonding of Ge 105 on the MEMS substrate 111 with the aluminum 108 of the base substrate 107. The bump stop 110a on base substrate 107 is a stationary structure that limits the motion of the moveable structure 106a. In an embodiment, the MEMS substrate 111 and the base substrate 107 are bonded to form the base substrate-MEMS device 100. In an embodiment, bump stop 110a has a layer of silicon nitride (SiN) 112 over a layer of silicon oxide 109. Both Si and SiN surfaces are smooth with a roughness of about 0.5 to 2.5 nm (rms) without a surface treatment or etch.

FIG. 1B shows a cross section drawing of the bonded base-substrate MEMS device 100 with movable structure 106b which can move and touch the bump stops 110b on the base substrate. In this embodiment, one of or both movable structure 106b surface and bump stop 110b surfaces can be roughened.

By roughening one or both of the surfaces, the area of atomic contact is reduced and hence the adhesion energy or stiction force is reduced. Surface roughening can be done by etching the surfaces of the movable structure 106b or the surfaces of stationary bump stops 110b in a gas, plasma, or liquid with locally non-uniform etch rate. In this embodiment, the surface of the movable structure 106b or the surface of the bump stop 110b, or both surfaces can be roughened by various processing techniques to reduce the area of atomic surface contact, and thus the adhesion force when the movable structure 106b comes in contact with bump stop 110b. In an embodiment, the movable structure 106b can be made of silicon and the bump stop 110b can be made of SiN. Other embodiments can have bump stop 110b surfaces made of any other material such as silicon oxide, aluminum or, titanium nitride (TiN).

In an embodiment, FIGS. 2A-2E show a series of cross section drawings of base substrate processing steps to complete a base substrate with bump stops having a rough surface. FIG. 2A shows the cross-section of a base substrate 107 with a conductive layer 108 such as aluminum (Al) deposited, patterned and etched. As shown in FIG. 2B, an Inter-Metal Dielectric (IMD) silicon oxide layer 109 is deposited on patterned conductive layer 108 and chemical mechanical polished (CMPed) to planarize the IMD silicon oxide layer 109. FIG. 2C shows a blanket passivation SiN film 112 deposited on the planarized IMD silicon oxide layer 109. The SiN film 112 has a smooth surface with a root-mean-square (RMS) roughness in the order of 1-3 nm (nanometers). In an embodiment, to initiate the surface roughening process, a thin film of silicon carbide (SiC) or amorphous Si (not shown) can be deposited onto the SiN film 112.

FIG. 2D shows the cross section of a base substrate 107 with a roughened SiN surface 112a achieved by local non-uniform etching with wet chemical, gas, or plasma processing. In an embodiment with bump stops with a top layer of SiN film, roughness can be obtained from oxygen-free plasma etching of SiN film 112 using a mixture of CF₄/H₂ or SF₆/CH₄/N₂ gas combinations. In the embodiment with bump stops with a top layer of SiC or amorphous Si film, the SiC or amorphous Si film can be etched with a plasma etch followed by further SiN etch for rougher surface.

FIG. 2E shows the cross section of the completed base substrate 107 after passivation SiN, and patterning and etching IMD silicon oxide layer 109a to form bump stop 110b, with a top layer of SiN 112a with a rough surface on bump stop 110b.

FIGS. 3A-3D show a series of cross section drawings of MEMS substrate 300 processing steps to complete the MEMS device with moveable structures having a rough surface in an embodiment. FIG. 3A shows a cross-section of an engineered SOI (ESOI)) wafer 310 comprised of a device layer 307 and a handle substrate 301 with cavities. The device layer 307 and a handle substrate 301 are bonded with a thin dielectric film 102 in between. In an embodiment, the device layer 307 can be thinned before subsequent bonding to a base substrate. A Ge film 305 is deposited onto the device layer 307 followed by coating and patterning photoresist 302 to define a standoff. In an embodiment, as shown in FIG. 3B, a wet etching step can be performed on the Ge film 305r and a dry etching can be performed on a portion of the device layer 307 to expose a surface 303a of the device layer 307 to form standoff 304 with a Ge film 305 on top.

In an embodiment shown in FIG. 3C, the standoff 304 is etched after depositing and patterning the Ge film 305. As shown in FIG. 3C exposed surface 303a is etched to form a rough surface 303b, followed by the removal of the patterned photoresist 302 and cleaning of the wafer. In different embodiment, the standoff 304 is patterned and etched before depositing and patterning Ge film 305.

In an embodiment, the surface 303a of the device layer 307 can be roughened by a plasma-less process such as isotropic silicon wet etch or isotropic silicon dry etch processes. Xenon diflouride (XeF2) dry chemical etch is an example of isotropic etch processes. In an embodiment, the wet etchant contains choline (C₅H₁₄NO), potassium hydroxide (KOH), sodium hydroxide (NaOH), lithium hydroxide (LiOH), ethylene diamine pyrocatechol (EDP), tetramethylammonium hydroxide (TMAH), or TMEH. Examples of plasma-less etching gases are xenon diflouride (XeF₂), bromine difluoride (BrF₂), iodine pentafluoride (IF₅), bromine pentafluoride (BrF₅), chlorine triflouride (ClF₃), or fluorine (F₂).

In an embodiment, the surface 303a of the device layer 307 can be roughened by a plasma etch. Sulfur hexafluoride (SF₆) plasma dry etch processes is an example of plasma etching process. In an embodiment, the plasma etching gas contains at least one of SF₆, CF₄, Cl₂, HBr, He, Ne, Ar, Kr, or Xe. In an embodiment, the roughness of the etched surface 303a could be in the order of 5-20 nm.

FIG. 3D, shows a completed MEMS substrate 300. In an embodiment, the rough device layer 307 is patterned, and etched to release the MEMS structure 306, Later, MEMS structure 306 is cleaned.

FIGS. 4A-4D show a series of cross-section drawings of a second embodiment of the processing steps of providing a rough surface on a silicon substrate.

In an embodiment, FIG. 4A shows a silicon substrate 402 with a smooth surface. FIG. 4B shows a thin layer of a film 404 with a rough surface deposited onto the smooth surface of the silicon substrate 402 to initiate the roughness. In an embodiment, the rough film 404 can be made of poly silicon or silicon carbide. In some embodiments, the rough film 404 provides a rough surface on the silicon substrate 402 and no further etching is required, steps shown in FIG. 4C and FIG. 4D are optional. Other embodiments include further etching of the rough surface. FIG. 4C shows an intermediate step of etching the rough film 404, resulting in a thinner film 404a. In an embodiment, the etching step can be performed by wet etching or dry etching. FIG. 4D, shows the final step, where further etching transfers the roughness of the rough film 404a to the silicon substrate 402a.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the present invention.

What is claimed is:

1. An integrated MEMS device comprising:
a MEMS substrate having a first contacting surface; and
a base substrate coupled to the MEMS substrate having a second contacting surface; wherein at least one of the first contacting surface and the second contacting surface is roughened.

2. The device of claim 1, wherein the MEMS substrate includes a handle layer coupled to a device layer; wherein the device layer comprising a movable structure suspended above and parallel to the base substrate.

3. The device of claim 2, wherein the MEMS substrate faces one or more fixed bump stops on the base substrate.

4. The device of claim 3, wherein the roughness of a surface of the movable structure facing the base substrate is greater than 4 nm-rms.

5. The device of claim 3, wherein roughness of the one or more fixed bump stops is greater than 4 nm-rms.

6. The device of claim 3, wherein one or more fixed bump stops is a dielectric material.

7. The device of claim 3, wherein the one or more fixed bumps is a conducting material.

8. The device of claim 3, wherein the one or more fixed bumps is a semiconducting material.

9. The device of claim 2, wherein the movable structure is a portion of any of an actuator, accelerometer, a microphone, a gyroscope, a pressure sensor, or a magnetometer.

10. The device of claim 2, wherein the handle layer includes a cavity.

11. A method to reduce surface adhesion forces in an integrated MEMS device; the integrated MEMS device including a MEMS substrate having a first contacting surface and a base substrate coupled to the MEMS substrate having a second contacting surface, the method comprising:
etching at least one of the first contacting surface and the second contacting surface to roughen the at least one of the first contacting surface and the second contacting surface.

12. The method of claim 11 wherein the etching comprises using a plasma-less etching gas to roughen the surface.

13. The method of claim 12, where the plasma-less etching gas contains at least one of xenon and fluorine.

14. The method of claim 11, wherein the etching comprises using a plasma etching gas to roughen the one contacting surface.

15. The method of claim 14, where the plasma etching gas contains at least one of SF₆, CF4, F2, O2, N2, CH4, and Xe.

16. The method of claim 11 wherein the etching comprises using a wet etchant to roughen the one contacting surface.

17. The method of claim 16, where the wet etchant contains choline, KOH, NaOH, LiOH, TMAH, or TMEH.

18. A method to reduce surface adhesion forces in an integrated MEMS device; the integrated MEMS device including a MEMS substrate having a first contacting surface and a base substrate coupled to the MEMS substrate having a second contacting surface, the method comprising:
depositing a rough film onto one of the first contacting surface and the second contacting surface; and
plasma etching the rough film through and into the one of the first contacting surface and the second contacting surface; wherein the roughness on the rough film is transferred into the one of the first contacting surface and the second contacting surface.
